(19) United States
(12) Patent Application Publication
(10) Pub. No.: US 2007/0120270 A1
(43) Pub. Date: May 31, 2007

(54) Flip chip hermetic seal using pre-formed material

(76) Inventor: Roger T. Kuroda, Poway, CA (US)

Correspondence Address: SMITH, GAMBRELL & RUSSELL, 1850 M STREET, N.W., SUITE 800, WASHINGTON, DC, 20036, US

(21) Appl. No.: 11/602,988

(22) Filed: Nov. 22, 2006

Related U.S. Application Data
(60) Provisional application No. 60/739,010, filed on Nov. 23, 2005.

(51) Int. Cl. H01L 23/48

(52) U.S. Cl. 257/778

(57) ABSTRACT

A flip chip architecture providing a hermetic seal. A flip chip die is assembled so as to be in contact with a package substrate. A pre-form of seal material is placed such that it surrounds the flip chip die and is in contact with the package substrate. The pre-form material is then processed so that it becomes a hermetic seal between the flip chip die and the substrate.

### CROSS REFERENCE TO RELATED APPLICATIONS

This application claims benefit to provisional application 60/739,010 filed on Nov. 23, 2005

### STATEMENT REGARDING FEDERALLY SPONSORED RESEARCH

These inventions were not developed using any funds of the United States of America.

### BACKGROUND AND SUMMARY

The inventions described and claimed herein relate in general to electronic circuits, and more specifically, to microelectronic assembly of circuits. Since the original concept of flip-chip assembly of dies to mating surfaces was suggested, many attempts have been made to develop flip-chip techniques using various technologies and processes. The inventions described herein comprise novel combinations of previously used individual structures in combination with a type of seal ring that has not previously been used in the microelectronic circuit assembly industry. The inventions also include a manufacturing process. One advantage of the novel architecture described herein is that a high-quality hermetic or quasi-hermetic seal can be obtained at small size, complexity, and very low cost, all of which being important for many types of sensors, actuators, and microelectronic circuits.

The following terms/phrases used in this patent document have generally accepted meanings in electrical engineering literature and will not be specifically defined herein: resistance, component, circuit, electrons and electronic, control, signal, voltage, current, power, energy, frequency, Hertz, Megahertz (MHz), Gigahertz (GHz), radio-frequency (RF), microwave, millimeter-wave, and all terms of the S.I. and English unit systems.

Other terms/phrases, relied upon in this document, particularly in the detailed description of the embodiments shown in the drawings, are now defined:

“Hermetic” refers to a level of seal quality used in the microelectronic industry. The inventions described herein provide hermetic or quasi-hermetic seals. For purposes of this document, the term hermetic is assumed to define “hermetic or quasi-hermetic”, representing a required level of permeability of a variety of gases and liquids for the devices inside to function properly. Industry definitions of these terms are often debated and vary between groups and over time.

As an example, in a first embodiment of these inventions, a type of glass is used to form the seal, which would be deemed hermetic by some members of the industry, and deemed quasi-hermetic by other members of the industry. A debate of the many competing definitions and usages of these terms is beyond the scope of this document, so the general term “hermetic” used herein to denote “hermetic enough for the device inside”.

“Pre-form” refers to the action of manufacturing a solid material by one of many forming techniques in the material industry. The solid material is typically of a homogenous or aggregate composite nature, but can also be a specific engineered combination of materials. The term is also, and most typically, used in the industry as a noun referring to a specific component that has been manufactured by such forming techniques. It is also used to refer to the pre-cursor material that is ultimately transformed into finished work product.

A “μm”, “micron”, or “micrometer” is a unit of length equal to one-one-thousandth of a millimeter.

“Microfabrication” is a fabrication method of defining components delineated through photolithographic techniques made popular by the integrated circuit developer community. Micromachining is the action of delineating a microfabricated element that has been photolithographically defined, often performed by an etching process using acids or bases.

“MEMS” and “MEMS devices” are Microfabricated ElectroMechanical Systems, which denotes a manufacturing technology that uses microfabrication techniques to develop miniaturized mechanical, electromechanical, and thermomechanical components. MEMS devices in this context typically refers to actuators such as switches, relays, and variable capacitors.

The inventions described herein utilize modifications to traditional flip-chip technologies and architectures that create a hermetic seal. The majority of flip-chip technologies and architectures do not provide a hermetic or quasi-hermetic seal, because sealing is not required for most circuits to function properly. Therefore, this invention is of particular interest to developers of circuits that do require a hermetic seal in order to function.

A number of attempts to provide hermetic seals to flip-chip components have been proposed because of the growing profusion of sensitive electronic circuits, sensors, and actuators that must be protected from the environment. Devices such as MEMS sensors and actuators are often particularly sensitive to many environmental influences, and must be protected by a hermetic enclosure of some sort in order to provide reliable, reproducible performance over their operational lifetime.

Most of the hermetic sealing techniques in the industry employ seal ring techniques in which a seal material is manufactured directly onto either the die or the mating substrate. Kurogi, et al. in U.S. Pat. No. 5,699,611 and U.S. Pat. No. 5,578,874, discuss several early examples of this type of seal ring being used in a flip-chip attachment architecture. According to Kurogi's teaching, a solder seal ring is microfabricated directly to the face of the flip-chip die. A mating ring is present on the package to which the die is attached. There are many contemporary arrangements and processes used in the industry that employ variants of Kurogi's architecture using a variety of metals, solders, glasses, and epoxies to form a seal.

However, there are disadvantages associated with the use of Kurogi's architecture and it's variants now used in the industry. One significant disadvantage of that architecture is that additional die space is required for the seal ring. The cost of the die is dependent on the size, so additional size used for the seal results in higher cost per die. This is of continuously increasing significance as microfabrication processes are developed with finer feature sizes for microelectronic circuits, sensors, and actuators. There are sensor products in which the seal ring is larger than the sensor and circuit combined, and therefore responsible for the majority of the cost of the die.

Other disadvantages of Kurogi's architecture and similar architectures relate to the process of manufacture. The process of depositing a particular desired seal material (for particular requirements of hermeticity) may not be compatible with the manufacturing process optimal for a particular circuit die. Also, many hermetic flip-chip techniques used in industry have a limited number of environments that can be contained within the cavity, because the flip-chip connection for the signal lines is formed at the same time as the bond. Bond and seal fabrication of many wafer-scale MEMS packages is responsible for many reliability problems and yield loss. Wafer-scale packaging processes often have yield that varies between 10% and 90%, which directly relates to increased cost.

Additional concerns are in flip-chip and seal quality inspection. The materials are situated between the die and package, so unless one of the two mating materials are transparent, quality inspection can be an additional burden in manufacturing. Particular manufacturing defects might only be detectable using expensive specialize equipment or processes, such as X-ray microscopy or ultrasonic micro-sonography, instead of using low-cost visible inspection techniques widely used throughout the microelectronic assembly industry.

The inventions described herein are the first flip-chip die seal architectures to attain a highly effective hermetic seal using a wide variety of materials and enabling a high quality of electrical interconnect with minimal limitations and difficulty in implementation. They solve long-standing problems of the microelectronic and MEMS industries by providing a low-cost seal technique that can be used as a modification of existing flip-chip processes.

The inventions described herein overcome the limitations of alternative flip-chip sealing techniques by providing a separate solder material as a separate low-cost component. The process of establishing the seal can be performed quickly and inexpensively assembled. This process can be carried out separately from the process of forming flip-chip connection to provide a specific environment inside the sealed cavity. These inventions also allow a wider variety of flip-chip die attachment techniques to be used in the assembly of a particular device, as a different seal process can be used, and therefore decouple reliability, yield, and process development. Also, because the seal is primarily external to the hidden mating surfaces of the die and package, seal quality can be easily inspected using conventional low-cost techniques and equipment.

The inventions described herein use pre-forms in order to provide a low-cost method of applying the seal material to the flip-chipped die. A wide variety of potential seal materials can be manufactured in pre-forms, which are used in a variety of other industries for forming seals, including glass, solder, metal, epoxy, and liquid-crystal polymers.

### BRIEF DESCRIPTION OF THE DRAWINGS

In the drawings, like reference numerals denote like or corresponding elements. The figures show various views of flip-chip dies with hermetic seal rings, and identify the most prominent features of the arrangements shown. Objects are defined using cross-hatching, succinct black borders, and numeration. All objects shown in light cross-hatching represent components that are typically manufactured of electrically insulating materials. Objects shown in dark cross-hatched patterns represent components and transmission lines that are typically electrical conductors, or represent more complex circuit elements common to the industry. Objects shown in medium cross-hatched patterns represent seal ring features themselves, which may be a combination of electrically insulating and conducting materials depending on the particular embodiment of the invention.

FIG. 1 is a cross-sectional schematic of an assembled, packaged, and sealed device according to a first, relatively simple, embodiment of the inventions.

FIG. 2 is a plan-view schematic of the assembled, packaged, and sealed device shown in cross section in FIG. 1. All objects are drawn as if opaque, so not all critical aspects of these inventions can be seen in this figure. The objects in this view have maintained the identical cross-hatch pattern in order to facilitate the identification of the same/corresponding objects shown in FIG. 1.

FIGS. 3A, 3B, 3C, 3D, and 3E are side-view cross-sectional schematic diagrams that illustrate assembly and manufacturing of a flip chip architecture having a hermetic seal.

FIG. 3A is the toroidal ring pre-form (illustrated as a cylindrical or rectangular toroid) of the seal material.

FIG. 3B is the flip-chip die itself prior to the flip-chip assembly operation.

FIG. 3C is the package substrate prior to assembly.

FIG. 3D is the die and package substrate after flip-chip assembly.

FIG. 3E adds the toroidal seal pre-form placed around the flip-chip die. The next process step leads to the assembly shown in FIG. 1.

FIG. 4 is an isometric schematic of an embodiment that is more complex than the one shown in FIGS. 1 and 2.

### DETAILED DESCRIPTION

The inventions described herein generally relate to a novel seal ring arrangement that provides a circuit, sensor, or actuator on a flip-chip die with a hermetic seal at a low cost and low manufacturing complexity. The following description first discusses this functional combination of flip-chip and seal technologies, then continues with a detailed discussion of several of the contemplated embodiments of this invention.

FIG. 1 is a cross-sectional schematic of an assembled, packaged, and sealed device according to a first, relatively simple, embodiment of the inventions. Critical elements of the inventions are shown in FIG. 1. The device die 10 is shown attached by a flip-chip assembly method to a package substrate 20. A device die would typically have two or more signal input/output lines which are used to bring electrical signals containing power, reference information, or data into or out of the device die. FIG. 1 shows two such signal input/output lines represented by a first die interconnect pad 11 and a second die interconnect pad 14. One important purpose of these inventions is to enable external electrical access to these two signal input/output lines. It is contemplated that these signal input/output lines can be used for direct current signals such as ground, power, logic, control, or data, and that they might also be designed for carrying radio-frequency, microwave, or millimeter-wave signals.

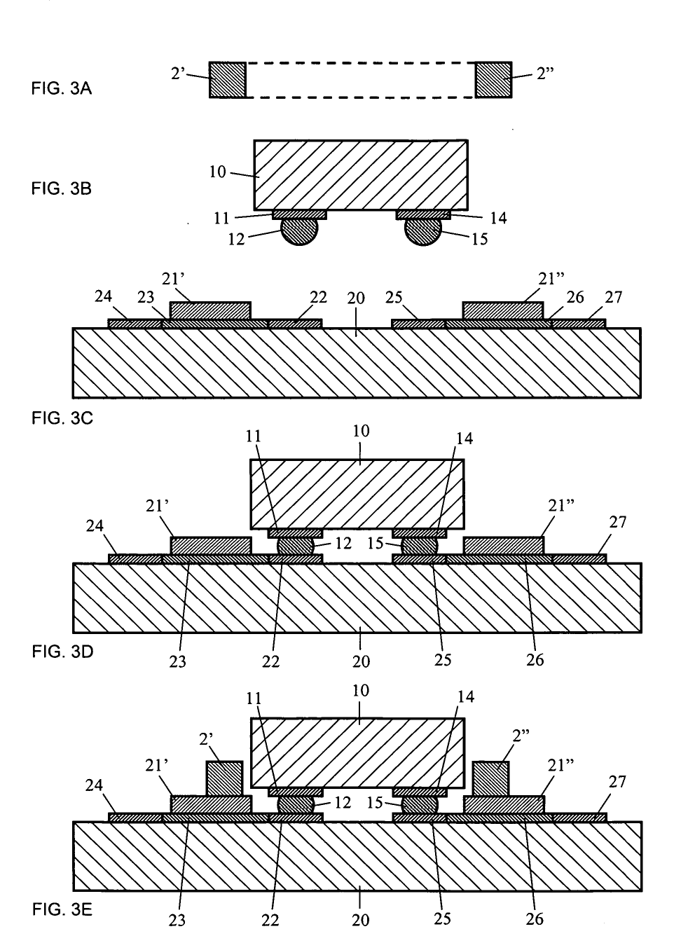

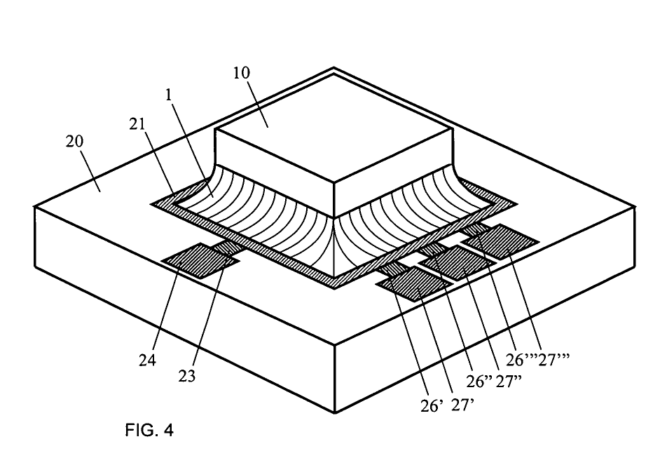

Flip-chip assembly techniques are used in the industry to make electrical connections from device dies to package substrates, which is one critical step in these inventions. The flip-chip interconnect itself is shown with the first die interconnect pad being mechanically and electrically connected to a first package interconnect pad 22 through a conducting first flip-chip bump 12. Similarly, the flip-chip assembly has the second die interconnect pad mechanically and electrically connected to a second package interconnect pad 25 through a conducting second flip-chip bump 15. Example considerations regarding the manufacturing and assembly of these various elements of the device die and package substrate are discussed in the descriptions of FIGS. 3B and 3C.

With this structural arrangement, the signal lines are available on the package, and extend to the exterior regions of the package in order to enable external electrical access. External access is typically achieved by bringing signals out on the surface of the package, or by pulling them through the package and getting access on the bottom surface. In the FIG. 1 embodiment, signals are brought out on the top surface of the package. The first package interconnect pad is attached to a first package signal line 23, which is then attached to a first package signal pad 24 which is exposed to the outside region of the package for electrical access. Similarly, the second package interconnect pad is attached to a second package signal line 26, which is then attached to a second package signal pad 27 for external electrical access. Features described thus far are typical for flip-chip assembly techniques used in the microelectronic assembly industry.

The inventions described herein combine the typical type of flip-chip assembly technologies described above with a family of seal ring technologies. The seal ring itself circumferentially sits around the device die, sealing the sides with a hermetic type of seal. This is shown in FIG. 1 where a first seal ring region 1′ and a second seal ring region 1″ are in mechanical contact with side walls of the device die, making a hermetic interface with the die. The illustrated cross-section of the seal ring elements is representative of a material that has been softened or liquefied, then hardened or resolidified with a material surface curvature characteristic of these types of manufacturing processes.

The first seal ring region is in mechanical contact with the top surface of a first protective ring region 21′ that makes a hermetic interface. The first protective ring region is in intimate mechanical contact with the first package signal line (mechanical contact seen in FIG. 1) and package substrate (mechanical contact not seen in FIG. 1), and can be considered part of the manufactured package for purposes of discussing the embodiment shown in FIG. 1. In a mirrored fashion, the second seal ring region is in mechanical contact with the top surface of a second protective ring region 21″ that also makes a hermetic interface. The second protective ring region is in intimate mechanical contact with the second package signal line, and all of these hermetic interfaces together provides a hermetic seal protecting the interior of the package and bottom surface of the device die from the external environment.

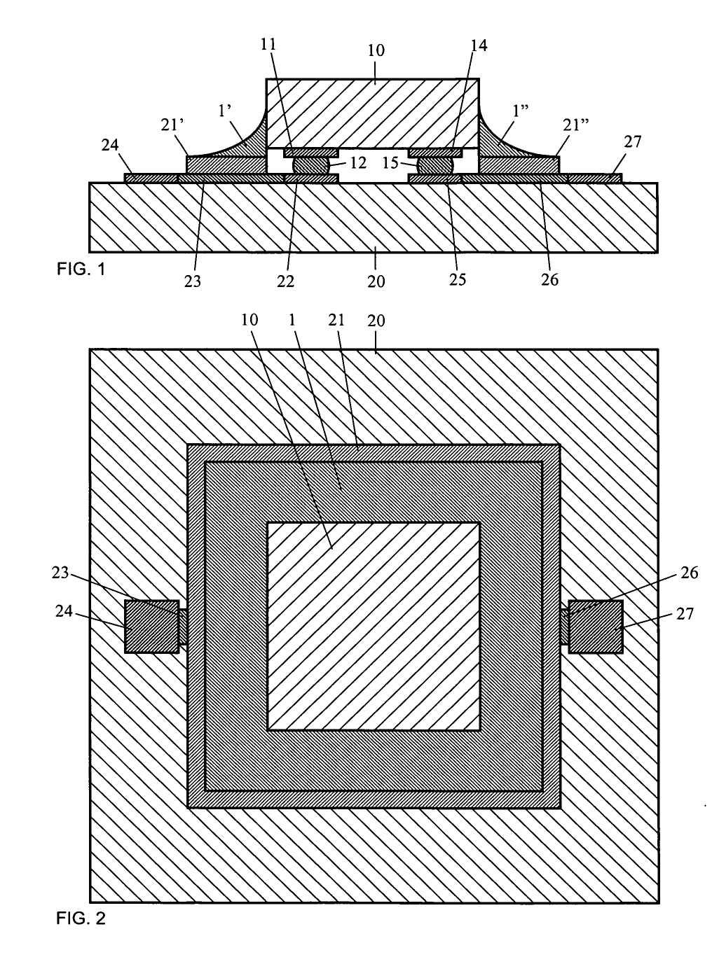

FIG. 2 is a plan-view schematic of the embodiment illustrated in FIG. 1. This figure illustrates the circumferential nature of the rings that create the complete seal around the device die. The device die is shown as the center square, which is entirely surrounded by a circumferential seal ring 1, comprising both the first and second regions discussed with respect to FIG. 1. Surrounding this seal ring is a circumferential protective ring 21 which is used to provide a good mechanical contact and seal between the seal ring and the package substrate.

FIGS. 3A, 3B, 3C, 3D, and 3E describe the manufacturing and assembly of the arrangement shown in FIG. 1. FIGS. 3A, 3B, and 3C illustrate three separate elements that are combined in the assembly process to create the arrangement shown in FIG. 1. FIG. 3D is the first assembly step, which is the flip-chip process. FIG. 3E is the second assembly step, which shows placement of the seal pre-form into position around the device die. The final process steps convert the seal pre-form into the seal ring with hermetic seal as described in the arrangement shown in FIG. 1.

FIG. 3A is the seal pre-form of the seal material. The pre-form is shown for this embodiment as a cylindrical or rectangular toroidal ring. Both cylindrical and rectangular toroids have the cross-sectional view shown in FIG. 3A. The seal pre-form is shown as being of a homogeneous material, with two equivalent cross-sectional regions shown: a first seal pre-form region 2′, and a second seal pre-form region 2″. The seal pre-form is manufactured of a pressed glass with a melting temperature between 250° C. and 350° C.

It is contemplated that in other embodiments of the inventions, different cross-sections for seal pre-forms can be used. It is also contemplated that many materials and combinations of dissimilar materials can be used to manufacture the seal pre-form, including plastics, glasses, and metals. Example plastics include, but are not limited to, B-stage epoxies, polyimides, polyamides, and liquid-crystal polymers. Example glasses include, but are not limited to, glass frits, low-temperature glasses (described above), and high-temperature glasses (with melting temperatures above 350° C.). Example metals include, but are not limited to, metals that may include gold, copper, palladium, tin, lead, and indium, and alloys and eutectics such as lead-tin, gold-tin, gold-indium, and other solder alloys and eutectics used in the microelectronic industry. Other suitable materials include, among others, plastics and liquid-crystal polymers (LCP). Covering glasses, eutectics, and solders are among the most promising materials with LCP also being highly useful.

FIG. 3B is a prepared circuit, sensor, or actuator die ready for flip-chip assembly. The device die is the primary object, with the devices requiring hermetic seal on the bottom surface of the die. The die has a first die interconnect pad and a second die interconnect pad with functions discussed in the detailed description of FIG. 1. In preparation for flip-chip assembly, it is common for device dies to be provided with flip-chip bumps, which are the elements used for both electrical and mechanical connection to the package. The flip-chip bumps are shown in FIG. 3B as a first flip-chip bump and a second flip-chip bump. Flip-chip bumps are typically added to the device dies rather than the package substrates, but both situations are contemplated in these inventions, as each is used in industry. In this embodiment, the flip-chip bumps are comprised of a gold alloy, and were added to the device die using a commercial wire bonder. It is contemplated that the flip-chip bumps can be comprised of a variety of metals, metal alloys, and metal eutectics as is seen throughout the microelectronic industry. Example metals and metal alloys include aluminum, aluminum alloys, gold, gold alloys, silver, silver alloys, gold-tin, gold-indium, lead-tin, and other microelectronic industry solder alloys and eutectics.

FIG. 3C illustrates the critical features of a package for one embodiment of these inventions. The package substrate is the base material upon which the other elements are manufactured. The other elements include the first package interconnect pad connected to a first signal line. The first signal line has been partially covered by a first protective ring region, and is connected to a first signal pad. Similarly, a second package interconnect pad is connected to a second signal line. The second signal line is partially covered by a second protective ring region and is connected to a second signal pad.

The two protective ring regions are illustrated as being part of the package, so the entire protective ring would have been manufactured atop the package substrate and signal lines. It is also contemplated that the protective ring could be manufactured as part of the seal pre-form, and would hence make an intimate connection and interface with the substrate at a later point in the assembly process.

The base material comprises a ceramic material which is then microfabricated to manufacture the additional elements atop the package substrate. It is recognized that certain embodiments of these inventions will manufacture the package elements primarily using the microfabrication processes of the microelectronics industry, although a variety of manufacturing techniques from the printing and forming industries are also contemplated. Alternative printing techniques include, but are not limited to, screen printing, laser marking, and thermal printing. Alternative forming techniques include, but are not limited to, embossing, laminating, thermoforming, sintering, and pressing.

The first package interconnect pad, second package interconnect pad, first signal line, second signal line, first signal pad, and second signal pad have all been manufactured at the same time using microfabrication techniques. All of these elements are made of the same stack of metal materials, which is a multi-layered combination of chrome, nickel, and gold that is typical for the microelectronic industry. It is contemplated that these elements can be comprised of a variety of metals, metal alloys, and metal eutectics as is seen throughout the microelectronic industry. Example metals include, but are not limited to, chrome, nickel, titanium, aluminum, gold, silver, palladium, tin, copper, alloys and eutectics using these metals, and other microelectronic industry alloys and eutectics.

The protective ring has additional purposes in different embodiments of these inventions. In this embodiment it is manufactured of a high-temperature glass material that is fired on top of the signal lines and package substrate. It is contemplated that the protective ring can be manufactured of a variety of insulating materials that provide desirable electrical signal isolation or protection in particular embodiments.

FIG. 3D is a side-view cross-sectional schematic of the die and package assembled together using a flip-chip assembly technique. All elements and their functions have already been described. The importance of this figure is to note that this first step of assembly uses the objects depicted in FIGS. 3B and 3C. The die has been pressed into intimate electrical and mechanical contact with the package, making contact between the first flip-chip bump and the first package interconnect pad, as well as the second flip-chip bump and the second package interconnect pad. In this embodiment, the die and package are pressed together with a combination of heat, pressure, and ultrasonic energy in one version of a family of processes called thermosonic flip-chip processes. Thermosonic flip-chip processes are appropriate for a wide variety of device dies, packages, and flip-chip bump materials. It is also contemplated that a variety of other flip-chip processes used in the microelectronic industry can be employed to develop these inventions, including, but not limited to, thermocompression flip-chip, solder reflow flip-chip, and eutectic flip-chip processes.

FIG. 3E illustrates the next step in the assembly process of the embodiment of FIG. 1. The object described by FIG. 3D is taken, and the seal pre-form of FIG. 3A is placed around the device die to rest atop the protective ring. In this embodiment, the seal pre-form is simply placed manually atop the protective ring, and rests. It is contemplated that in other embodiments that the seal pre-form is placed by automated machines, and is held by a type of retaining force, adhesive, or tacky material until the next assembly step is carried out. Examples of such techniques include, but are not limited to, the use active or passive versions of magnetic attraction, electrostatic attraction (i.e., “static cling”), physical interlocking, or enhanced-friction surfaces. Examples of tacky materials include, but are not limited to, epoxy, resin, solder flux, wax, or polymers such as photoresist, polyimides, polyamides, or liquid-crystal polymers.

FIG. 4 is an isometric schematic of a more complex example of the embodiment shown in FIGS. 1 and 2. In this figure, the shape of the assembled die, seal ring, and package is shown without maintaining the cross-hatch identification of the previous figures except for the signal lines, signal pads, and protective ring. This example is more complex because it shows one signal line coming through the seal from one of the facings, and three signal lines coming through the seal from a second facing. A first side signal line 26′ is seen to emerge from beneath the seal ring and connect to an exposed first side signal pad 27′. Similarly, a second side signal line 26″ emerges from beneath the seal ring and connects to an exposed second side signal pad 27″. Also, a third side signal line 26′″ emerges from beneath the seal ring and connects to an exposed third side signal pad 27′″.

In this embodiment, four signal lines and pads are present. This arrangement illustrates that, in practice, many signal lines can be coming through the seal from many different facings, or come out from below the die itself. These inventions are not restricted to embodiments employing just a few signal lines or specific methods of bringing signal lines to the exterior surfaces of the package substrate. It is also contemplated that three signal lines could represent one center conductor of a coplanar waveguide transmission line, and two other signal lines be the side ground conductors of said transmission line. These and other device, design, and process modifications appropriate for those skilled in the art have been contemplated as embodiments of these inventions.

1. A flip chip architecture providing a hermetic seal, comprising:
a package substrate;
a flip chip die in contact with the package substrate;
a seal formed from a pre-form material in contact with the flip chip die and package substrate.

2. A process for manufacturing a flip chip architecture providing a hermetic seal, comprising:
providing a package substrate, a flip chip die, and a seal material pre-form;
assembling the package substrate with the flip chip die;
placing the seal material pre-form around the flip chip die so that it is in contact with a portion of the package substrate; and
processing the seal pre-form to become a hermetic seal between the flip chip die and package substrate.
